(19) United States
(12) Patent Application Publication
(10) Pub. No.: US 2012/0126771 A1
(43) Pub. Date: May 24, 2012

(54) CIRCUITRY FOR DETECTING A TRANSIENT

(75) Inventor: Charles Derrick Tuten, San Diego, CA (US)

(73) Assignee: QUALCOMM INCORPORATED, San Diego, CA (US)

(21) Appl. No.: 13/298,858

(22) Filed: Nov. 17, 2011

Related U.S. Application Data
(60) Provisional application No. 61/415,854, filed on Nov. 21, 2010.

(51) Int. Cl. G05F 1/10; G01R 19/00

(52) U.S. Cl. 323/284; 324/76.11

(57) ABSTRACT

Circuitry configured for detecting a transient is described. The circuitry includes an analog-to-digital converter that obtains a first voltage sample at a first time and a second voltage sample at a second time. The circuitry also includes a slope detector coupled to the analog-to-digital converter. The slope detector determines a first slope based on the first voltage sample and the second voltage sample. The circuitry further includes a threshold detector coupled to the slope detector. The threshold detector generates a first signal if the first slope exceeds a transient threshold.

### RELATED APPLICATIONS

This application is related to and claims priority from U.S. Provisional Patent Application Ser. No. 61/415,854 filed Nov. 21, 2010, for “FAST TRANSIENT DETECTION.”

### TECHNICAL FIELD

The present disclosure relates generally to electronic devices. More specifically, the present disclosure relates to circuitry for detecting a transient.

### BACKGROUND

In the last several decades, the use of electronic devices has become common. In particular, advances in electronic technology have reduced the cost of increasingly complex and useful electronic devices. Cost reduction and consumer demand have proliferated the use of electronic devices such that they are practically ubiquitous in modern society. As the use of electronic devices has expanded, so has the demand for new and improved features of electronic devices. More specifically, electronic devices that perform functions faster, more efficiently or with higher quality are often sought after. Some examples of electronic devices include circuitry, integrated circuits, processors, computing devices, wireless communication devices, etc.

Electronic devices may use one or more energy sources in order to function. Such energy sources provide electrical power (e.g., voltage, current) in order to enable electronic device functionality. For example, some electronic devices may include processors, integrated circuits, displays, communication interfaces, etc., that require electrical power to function. Some electronic devices use portable energy sources, such as batteries. For instance, a cellular phone may use a battery to function.

An energy source may provide a voltage that varies over time. For example, a battery may provide a voltage. Voltage may vary over time depending on the amount of current being consumed. For instance, when an electronic device consumes a significant amount of current, the voltage provided by a battery may drop. However, some electronic devices may not function properly if the voltage provided varies too much. As can be observed from this discussion, systems and methods that improve voltage regulation may be beneficial.

### SUMMARY

Circuitry configured for detecting a transient is described. The circuitry includes an analog-to-digital converter that obtains a first voltage sample at a first time and a second voltage sample at a second time. The circuitry also includes a slope detector coupled to the analog-to-digital converter. The slope detector determines a first slope based on the first voltage sample and the second voltage sample. The circuitry also includes a threshold detector coupled to the slope detector. The threshold detector generates a first signal if the first slope exceeds a transient threshold. The circuitry may be included in a buck converter.

The circuitry may also include controller override circuitry coupled to the threshold detector. The controller override circuitry may switch from a normal response mode to a transient response mode based on the first signal. The circuitry may additionally include driver circuitry coupled to the controller override circuitry. The driver circuitry may change a power level based on the transient response mode.

The analog-to-digital converter may also obtain a third voltage sample at a third time and a fourth voltage sample at a fourth time. The slope detector may also determine a second slope based on the third voltage sample and the fourth voltage sample. The threshold detector may further generate a second signal if the second slope exceeds an exit threshold.

The controller override circuitry may also switch from the transient response mode to the normal response mode based on the second signal. The driver circuitry may further change the power level based on the normal response mode.

The first voltage sample and the second voltage sample may include samples of a direct current voltage. The direct current voltage may be a supply voltage.

A method for detecting a transient with circuitry is also described. The method includes obtaining a first voltage sample at a first time and a second voltage sample at a second time. The method also includes determining a first slope based on the first voltage sample and the second voltage sample. The method further includes generating a first signal if the first slope exceeds a transient threshold.

A computer-program product for detecting a transient is also described. The computer-program product includes a non-transitory tangible computer-readable medium with instructions. The instructions include code for causing circuitry to obtain a first voltage sample at a first time and a second voltage sample at a second time. The instructions also include code for causing the circuitry to determine a first slope based on the first voltage sample and the second voltage sample. The instructions further include code for causing the circuitry to generate a first signal if the first slope exceeds a transient threshold.

An apparatus for detecting a transient is also described. The apparatus includes means for obtaining a first voltage sample at a first time and a second voltage sample at a second time. The apparatus also includes means for determining a first slope based on the first voltage sample and the second voltage sample. The apparatus further includes means for generating a first signal if the first slope exceeds a transient threshold.

### BRIEF DESCRIPTION OF THE DRAWINGS

FIG. 1 is a block diagram illustrating one configuration of circuitry in which systems and methods for detecting a transient may be implemented;

FIG. 2 is a flow diagram illustrating one configuration of a method for detecting a transient with the circuitry;

FIG. 3 is a flow diagram illustrating one configuration of a method for detecting an exit condition with the circuitry;

FIG. 4 is a block diagram illustrating another configuration of circuitry, including controller override circuitry and driver circuitry, in which systems and methods for detecting a transient may be implemented;

FIG. 5 is a flow diagram illustrating another configuration of a method for detecting a transient on the circuitry;

FIG. 6 is a flow diagram illustrating another configuration of a method for detecting an exit condition on the circuitry;

FIG. 7 is a block diagram illustrating one example of circuitry, including controller circuitry with a normal response mode and a transient response mode, in which systems and methods for detecting a transient may be implemented;

FIG. 8 is a diagram illustrating one example of a voltage variation and how a transient and an exit condition may be detected;

FIG. 9 is a block diagram illustrating one example of voltage regulator circuitry for supplying a voltage to a processor;

FIG. 10 is a timing diagram illustrating one example of transient detection in accordance with the systems and method disclosed herein;

FIG. 11 is a block diagram illustrating one configuration of a wireless communication device in which systems and methods for detecting a transient may be implemented; and

FIG. 12 illustrates various components that may be utilized in an electronic device.

### DETAILED DESCRIPTION

In various situations, it may be desirable to supply a load with a specific voltage. A transient may occur when a voltage is supplied that varies from that specific voltage to a particular degree. In some cases, the voltage may vary rapidly enough that normal control may not be sufficient to maintain the voltage within a specified range. Such variations in voltage may be referred to as “transients,” “fast transients” or other similar variations herein. In some cases, a transient may correspond to a fast load transient (e.g., a dramatic voltage variation caused by a change in current over a short period of time). It is noted that as used herein, the terms ‘transient’ and ‘fast load transient’ may be used interchangeably. In one configuration, the systems and methods disclosed herein may be used for transient detection. More specifically, the systems and methods disclosed herein may be used for transient detection based on slew rate. In other words, a transient may be detected based on the slope of a voltage change (when a change in voltage is reached within a specific change in time, for example).

In some cases, a transient may occur when a regulator cannot respond fast enough to changes in current. For example, when a large current load is applied (at a high attack rate, for example) faster than a regulator can respond, then a voltage drop may occur. Similarly, when a current load is removed (at high attack rate, for example) faster than a regulator can respond, then a voltage spike may occur. In these situations, a special response (e.g., nonlinear response) may be required. Additionally, a way to detect a transient so that the special response may be engaged may be required. One previous approach for transient detection utilized level sensitive engagement (detecting when a voltage level is reached, for example). For instance, if the desired voltage were 3 volts, then a transient may be detected if the voltage being supplied drops below 2.9 volts or spikes above 3.1 volts. In this approach, when the specified voltage level is reached, a special response may be engaged until the exit conditions are satisfied. One configuration of the systems and methods disclosed herein describes an approach for transient detection utilizing slew rate (e.g., slope based) engagement (detecting when a change in voltage is reached within a change in time, for example). In other words, when a delta voltage is reached within a delta time, a special response may be engaged until the exit conditions are satisfied.

Slope based detection may be beneficial because it allows for earlier detection of a transient by not having to wait until a maximum limit is reached. Some of the benefits associated with this approach may be illustrated in the following example. In a switching voltage regulator, the output voltage is approximately a triangle waveform centered at the desired voltage. Ripple associated with the waveform (e.g., the triangle waveforms peak to valley delta voltage) may be 10 millivolts (mV). In one configuration, a level based transient trigger may be set at −100 mV. It is noted that 100 mV is a reasonable value for this type of system, because if the trigger is set closer to the desired voltage, then the trigger may be more likely to engage due to noise and continually bounce between positive and negative trigger levels. In this approach (e.g., the voltage level based approach), the engagement is consistent, but larger than desired. In contrast, a slew rate (e.g., slope) based system can be tuned for a desired voltage delta that occurs in a desired time. This may enable the voltage ripple to be distinguished from the transients. Additionally, this may enable a fast load transient to be distinguished from a slow load transient, noise, and the like. The voltage engagement delta may also be tightened up considerably. For instance, 20 mV may be a reasonable voltage delta. With this method the engagement may occur as early as −10 mV or as late as −30 mV both much sooner than the −100 mV of the level based system.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods.

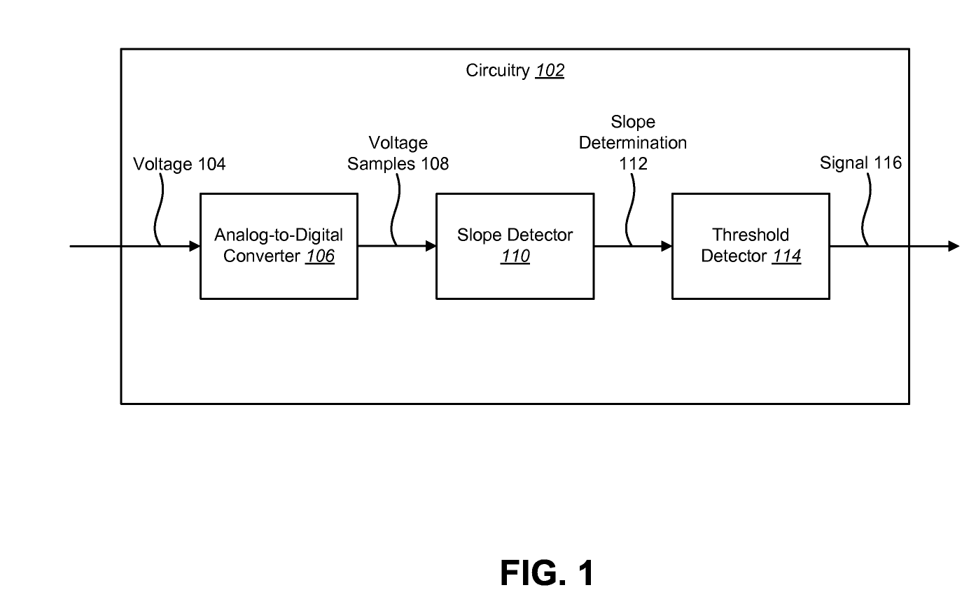

FIG. 1 is a block diagram illustrating one configuration of circuitry 102 in which systems and methods for detecting a transient may be implemented. The circuitry 102 may include an analog-to-digital converter 106, a slope detector 110 and a threshold detector 114. The analog-to-digital converter 106 may be coupled to the slope detector 110. The slope detector 110 may be coupled to the threshold detector 114. As used herein, the term “coupled” or variations thereof may mean that a first element is connected to a second element directly or indirectly. For example, if a first element is coupled to a second element, the first element may be connected directly to the second element or may be connected to the second element through another element.

The analog-to-digital converter 106 may receive a voltage 104 and may output voltage samples 108. The analog-to-digital converter 106 may sample the voltage 104 to produce the voltage samples 108. For example, the analog-to-digital converter 106 may sample a continuous direct current voltage (e.g., voltage 104) to produce digital voltage samples (e.g., voltage samples 108) of the direct current voltage. The voltage samples 108 may be values that may correspond to the magnitude of a voltage 104 at a particular time.

The slope detector 110 may receive the voltage samples 108 and may output a slope determination 112. The slope detector 110 may calculate the slope determination 112 based on two or more of the voltage samples 108. For example, the slope detector 110 may receive a first voltage sample 108 and a second voltage sample 108 and may calculate a slope determination 112 based on the magnitude of the first voltage sample 108, the magnitude of the second voltage sample 108 and the time difference between the first voltage sample 108 and the second voltage sample 108. The slope detector 110 may calculate the slope determination 112 based on consecutive or nonconsecutive voltage samples 108. In one configuration, the slope detector 110 may additionally detect a change in concavity (e.g., a peak or a valley of a voltage variation). It should be noted that the slope detector 110 may make a slope determination 112 regardless of whether the voltage samples 108 meet some predetermined criteria in some configurations. For example, some known approaches may first determine whether a voltage sample meets a voltage threshold before performing further operations based on the voltage sample, which is not required in at least some of the configurations of the systems and methods disclosed herein.

The threshold detector 114 may receive a slope determination 112 and may output a signal 116 if the slope determination 112 exceeds a threshold. The threshold detector 114 may compare the slope determination 112 with a threshold and determine if the slope determination 112 exceeds the threshold. The threshold may be a slope threshold. Additionally or alternatively, the threshold may vary depending on the application. In some configurations, the threshold detector 114 may include a transient threshold and an exit threshold (that satisfies an exit condition, for example). In this configuration, the threshold detector 114 may use the transient threshold until a transient is detected. Once the transient is detected, the threshold detector 114 may use the exit threshold until an exit condition (e.g., the end of a need for a transient response) is detected.

In another configuration, the transient detector 114 may additionally detect a change in concavity of a transient and/or may determine if a slope exceeds the exit threshold with the detection of the change in concavity. For example, the threshold detector 114 may determine whether the slope determination 112 exceeds a threshold (e.g., whether the slope determination 112 indicates a zero slope and/or other slope indicating recovery). For instance, the threshold detector 114 may generate a signal 116 if the slope determination 112 exceeds a threshold. The signal 116 may indicate that the slope exceeds the threshold (thus indicating a transient or an exit condition, for example). In one configuration, the signal 116 may indicate if the slope determination 112 is a positive slope or a negative slope. In some configurations, the threshold detector 114 may include two transient thresholds (e.g., a positive transient threshold and a negative transient threshold) for detecting increasing transients (e.g., voltage spikes) and decreasing transients (e.g., voltage dips or drops). Additionally or alternatively, the threshold detector 114 may include two exit thresholds (e.g., a positive exit threshold and a negative exit threshold) for detecting a negative exit condition (e.g., from a voltage spike) and a positive exit condition (e.g., from a voltage dip). Additionally or alternatively, the threshold detector 114 may determine whether the slope determination 112 indicates a zero slope. It should be noted that the term “exceed” and variations thereof as used herein may mean being “greater than” and/or being “greater than or equal to” in some configurations of the systems and methods described herein.

It should be noted that one or more of the elements illustrated as included within the circuitry 102 may be implemented in hardware, software or a combination of both. For example, the slope detector 110 and the threshold detector 114 may be implemented in hardware, software or a combination of both.

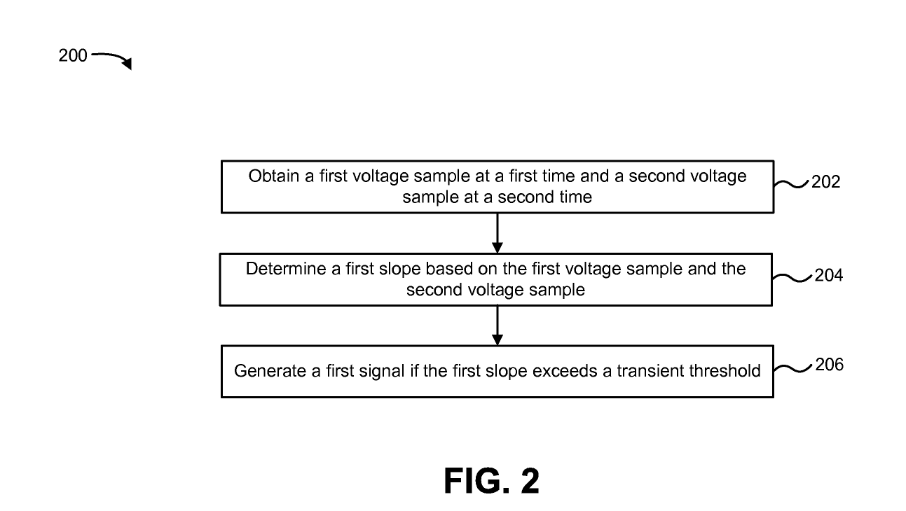

FIG. 2 is a flow diagram illustrating one configuration of a method 200 for detecting a transient with the circuitry 102. The circuitry 102 may obtain 202 a first voltage sample at a first time and a second voltage sample at a second time (e.g., voltage samples 108). For example, the circuitry 102 may obtain 202 a voltage sample by sampling a voltage 104 (with an analog-to-digital converter 106, for example). In another example, the circuitry 102 may obtain 202 a voltage sample by sampling an error voltage (e.g., the difference between the voltage 104 being supplied to a load and a desired voltage to be supplied to the load).

The circuitry 102 may determine 204 a first slope (e.g., a slope determination 112) based on the first voltage sample and the second voltage sample (e.g., voltage samples 108). More specifically, the first slope may be based on the magnitude of the first voltage sample, the magnitude of the second voltage sample, the first time and the second time. For example, if the magnitude of the first voltage sample taken at 0 nanoseconds (ns) were 0 mV and the magnitude of the second voltage sample taken at 100 ns were 11 mV, then the slope would be 11 mV/100 ns. In this example, the slope is a positive slope. However, in other examples, the slope may be a positive slope or a negative slope (e.g., −11 mV/100 ns). For example, if the magnitude of the first voltage sample is less than the magnitude of the second voltage sample, then the first slope may be a positive slope. In contrast, if the magnitude of the first voltage sample is more than the magnitude of the second voltage sample, then the first slope may be a negative slope. A positive slope may correspond to a voltage gain (e.g., voltage spike) and a negative slope may correspond to a voltage loss (e.g., voltage drop). In some configurations, the slope may be expressed in least significant bits (LSBs) per sample period. For example, a slope may exceed a transient threshold if it is greater than or equal to 2 analog-to-digital converter (ADC) LSB per 1 ADC conversion period.

It should be noted that the circuitry 102 may determine 204 the slope regardless of whether the voltage samples exceed one or more voltage thresholds in at least some configurations. For example, some known approaches require that a voltage sample exceeds a voltage threshold before performing further operations based on the voltage sample. However, this is not required in at least some of the configurations of the systems and methods disclosed herein.

The circuitry 102 may generate 206 a first signal (e.g., signal 116) if the first slope exceeds a transient threshold (e.g., threshold for detecting a transient). In other words, the circuitry 102 may generate 206 the first signal when the rate of change of a voltage variation exceeds a threshold (e.g., if the voltage variation is more positive than a positive threshold or more negative than a negative threshold). Thus, if a slope (e.g., slope determination 112) does not exceed a threshold (e.g., one of the positive threshold or negative threshold), then a signal indicating a transient is not generated. In contrast, if the slope exceeds the threshold, then a first signal (e.g., signal 116 that indicates a transient) is generated 206. In one configuration, the threshold may be based on a rate of change irrespective of whether the first slope is a positive slope or a negative slope. In another configuration, the threshold may be based on a rate of change and whether the first slope is a positive slope or a negative slope. In this scenario, the threshold for a positive slope may be different from the threshold for a negative slope. In some cases, the first signal may indicate if the first slope is a positive slope or a negative slope.

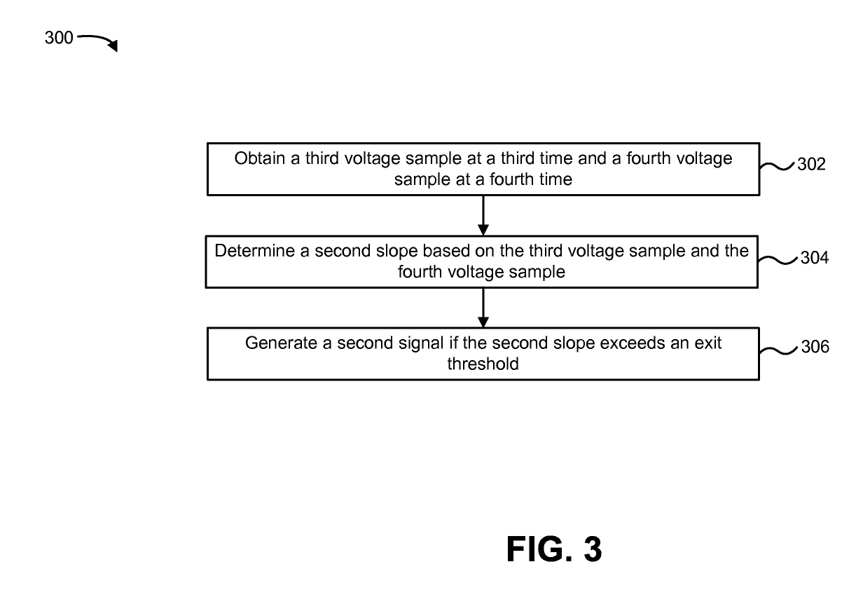

FIG. 3 is a flow diagram illustrating one configuration of a method 300 for detecting an exit condition with the circuitry 102. The circuitry 102 may obtain 302 a third voltage sample at a third time and a fourth voltage sample at a fourth time (e.g., voltage samples 108). For example, the circuitry 102 may obtain 302 a voltage sample by sampling a voltage 104 (with an analog-to-digital converter 106, for example). In another example, the circuitry 102 may obtain 302 a voltage sample by sampling an error voltage (e.g., the difference between the voltage 104 being supplied to a load and a desired voltage to be supplied to the load).

The circuitry 102 may determine 304 a second slope (e.g., a slope determination 112) based on the third voltage sample and the fourth voltage sample (e.g., voltage samples 108). More specifically, the second slope may be based on the magnitude of the third voltage sample, the magnitude of the fourth voltage sample, the third time and the fourth time. The second slope may be a positive slope or a negative slope. For example, if the magnitude of the third voltage sample is less than the magnitude of the fourth voltage sample, then the second slope may be a positive slope. In contrast, if the magnitude of the third voltage sample is more than the magnitude of the fourth voltage sample, then the second slope may be a negative slope. A positive slope may correspond to recovering from a voltage loss (e.g., voltage drop) and a negative slope may correspond to recovering from a voltage gain (e.g., voltage spike). It should be noted that the circuitry 102 may determine 304 the slope regardless of whether the voltage samples exceed one or more voltage thresholds in at least some configurations.

The circuitry 102 may generate 306 a second signal (e.g., signal 116) if the second slope exceeds an exit threshold (e.g., threshold for detecting an exit condition). For example, the circuitry 102 may generate 306 the second signal (e.g., signal 116) if the second slope is a zero slope and/or indicates recovery. In other words, the circuitry 102 may generate 306 the second signal when the rate of change of a voltage correction from a transient response is zero and/or exceeds (e.g., more positive than a positive threshold, more negative than a negative threshold) a threshold. For instance, if a slope (e.g., slope determination 112) is not zero and/or does not exceed the threshold (e.g., the appropriate exit condition), then a signal (e.g., signal that indicates an exit condition) is not generated. In contrast, if the slope is zero and/or exceeds the threshold, then the second signal (e.g., signal 116) is generated 306. In one configuration, the threshold may be based on a rate of change irrespective of whether the second slope is a positive slope or a negative slope. In another configuration, the threshold may be based on a rate of change and whether the second slope is a positive slope or a negative slope. In this scenario, the threshold for a positive slope may be different from the threshold for a negative slope. In some cases, the second signal may indicate if the first slope is a positive slope or a negative slope.

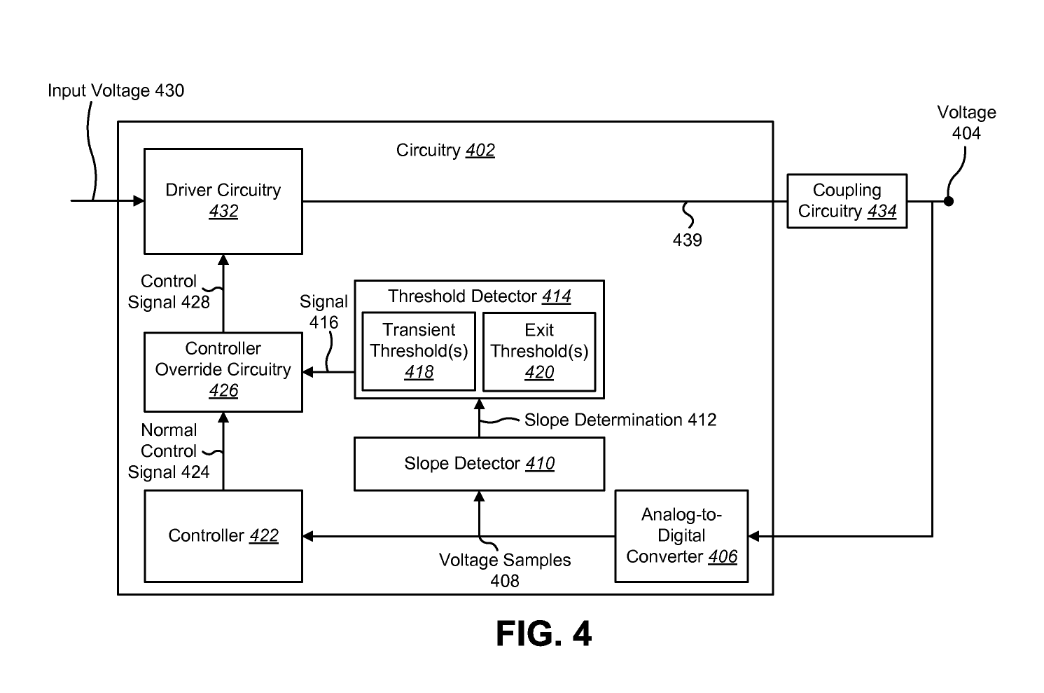

FIG. 4 is a block diagram illustrating another configuration of circuitry 402, including controller override circuitry 426 and driver circuitry 432, in which systems and methods for detecting a transient may be implemented. The circuitry 402 may be coupled to coupling circuitry 434.

An input voltage 430 may supply the driver circuitry 432 with electrical power. The driver circuitry 432 may supply a voltage 404 to a load through the coupling circuitry 434. For example, the driver circuitry 432 may create the voltage 404 by switching on and switching off the input voltage 430 to create a pulse train (e.g., a switch signal 439 at a specific duty cycle, for example). The driver circuitry 432 may be controlled by a control signal 428 and may change a power level (e.g., change a duty cycle) based on the control signal 428. The controller override circuitry 426 may provide the control signal 428 to the driver circuitry 432. It should be noted that in some configurations, the circuitry 402 (e.g., driver circuitry) may not operate using one or more current sources. For example, some known approaches may operate using one or more current sources, which is not required in at least some of the configurations of the systems and methods described herein.

The controller override circuitry 426 may provide the control signal 428 by propagating a normal control signal 424 as the control signal 428 or by providing a transient response signal as the control signal 428 (e.g., overriding the normal control signal 424). For example, when the controller override circuitry 426 has not received a signal 416 that indicates a transient, the controller override circuitry 426 propagates the normal control signal 424 as the control signal 428 (e.g., normal response mode). In this scenario, the driver circuitry 432 may output a 30% duty cycle if the controller 422 is directing that 30% duty cycle is to be output. In another example, when the controller override circuitry 426 has received a signal 416 that indicates a transient, the controller override circuitry 426 may provide a transient response control signal (e.g., overriding the normal control signal 424) as the control signal 428 (e.g., transient response mode). In this scenario, the driver circuitry 432 may immediately (e.g., concurrently upon detection of a transient) maximize the duty cycle (e.g., switch on and/or maximize the duty cycle for the current frame and for subsequent switching frames, 100% duty cycle on subsequent switching frames, for example) or minimize the duty cycle (e.g., switch off and/or minimize the duty cycle for the current frame and for subsequent switching frames, 0% duty cycle on subsequent switching frames, for example) depending on whether the transient is a voltage loss (e.g., drop) or a voltage gain (e.g., spike). The driver circuitry 432 may be coupled to the coupling circuitry 434 and may supply electrical power to the coupling circuitry 434 to create the voltage 404. The voltage 404 may be a supply voltage that supplies a load.

The coupling circuitry 434 may include elements for implementing various converter topologies. In some configurations, the circuitry 402 and the coupling circuitry 434 may constitute a converter (e.g., buck converter, buck-boost converter, boost converter, etc.). For example, the circuitry 402 may be included in a buck converter.

The analog-to-digital converter 406 may be coupled to the line that supplies the voltage 404 and may sample the voltage 404 to produce voltage samples 408. The analog-to-digital converter 406 may be similar to the analog-to-digital converter 106 described previously with respect to FIG. 1.

The slope detector 410 may be coupled to the analog-to-digital converter 406 and may determine a slope (e.g., slope determination 412) based on the voltage samples 408. The slope detector 410 may be similar to the slope detector 110 described previously with respect to FIG. 1.

The threshold detector 414 may be coupled to the slope detector 410 and may generate a signal 416 if the received slope determination 412 exceeds a threshold. The threshold detector 414 may be similar to the threshold detector 114 described previously with respect to FIG. 1. The threshold detector 414 may include one or more transient thresholds 418 and one or more exit thresholds 420.

The transient threshold(s) 418 may be used by the threshold detector 414 to detect a transient. For example, the transient threshold(s) 418 may identify a threshold slope (e.g., ±11 mV/100 ns) for detection of a transient. In one configuration, the threshold detector 414 may include a plurality of transient thresholds 418. For example, a transient threshold 418 for a positive slope and a (e.g., different) transient threshold 418 for a negative slope. The transient threshold 418 may be selected for detecting certain types of transients (e.g., a fast load transient) while ignoring other types of transients (e.g., noise, a slow load transient).

The exit threshold(s) 420 may be used by the threshold detector 414 to detect an exit condition. For example, the exit threshold(s) 420 may identify a threshold slope (e.g., a slope of zero (where a slope of zero may be no ADC change from one conversion to the next, for example), a positive slope following a negative slope (and/or zero slope) or a negative slope following a positive slope (and/or zero slope), plus an additional ADC LSB change) for detection of an exit condition. In one configuration, the transient detector 414 may include a plurality of exit thresholds 420. For example, an exit threshold 420 for a positive slope and a (e.g., different) exit threshold 420 for a negative slope). The exit threshold 420 may be selected to satisfy certain types of exit conditions (e.g., slope based, average slope based, etc.).

In one configuration, the threshold detector 414 may receive a first slope (e.g., slope determination 412) and compare that first slope with the transient threshold(s) 418. The threshold detector 414 may compare any slope determinations 412 received with the transient threshold(s) 418 until a slope determination 412 exceeds a transient threshold 418. Once the threshold detector 414 determines that a first slope exceeds the transient threshold 418, the threshold detector 414 will generate a first signal 416 and then may compare any future slope determinations 412 received with the exit threshold(s) 420 until a second slope exceeds an exit threshold 420. Once the threshold detector 414 determines that the second slope exceeds the exit threshold 420, the threshold detector 414 will generate a second signal 416 and then may compare any future slope determinations 412 with the transient threshold 418, thus restarting the cycle.

A controller 422 may also be coupled to the analog-to-digital converter 406 and may also receive the voltage samples 408. The controller 422 may determine a normal control signal 424 for the driver circuitry 432 based on the voltage samples 408. For example, if the voltage 404 is below a desired voltage, the controller 422 may generate a normal control signal 424 for the driver circuitry 432 to increases the duty cycle that is output.

The controller override circuitry 426 may be coupled to the threshold detector 414 and to the controller 422. The controller override circuitry 426 may receive the signal 416 from the threshold detector 414 and may receive the normal control signal 424 from the controller 422. The controller override circuitry 426 may propagate the normal control signal 424 to the driver circuitry 432 as the control signal 428 when a transient is not detected (e.g., in a normal response mode). In this scenario, the control signal 428 may be the same signal as normal control signal 424. However, when the controller override circuitry 426 receives a first signal (e.g., signal 416) from the threshold detector 414, the controller override circuitry 426 may override the normal control signal 424 with a transient response signal. In this scenario, the control signal 428 may be transient response signal instead of the normal control signal 424 (e.g., the normal control signal 424 is overridden by the transient response signal). The transient response signal may be sent to the driver circuitry 432 as the control signal 428 (e.g., transient response mode). For example, the controller override circuitry 426 may override the normal control signal 424 with a control signal 428 to establish a different duty cycle (e.g., 100%, 0%). The controller override circuitry 426 may override the normal control signal 424 until an exit condition occurs. For example, the controller override circuitry 426 may override the normal control signal 424 until a second slope (e.g., slope determination 412) exceeds an exit threshold 420 and the controller override circuitry 426 receives a second signal (e.g., signal 416). In some configurations, alternate exit conditions may be used (staying in transient response mode until the controller 422 is generating a normal control signal 424 that is sufficient for responding to a transient, for example).

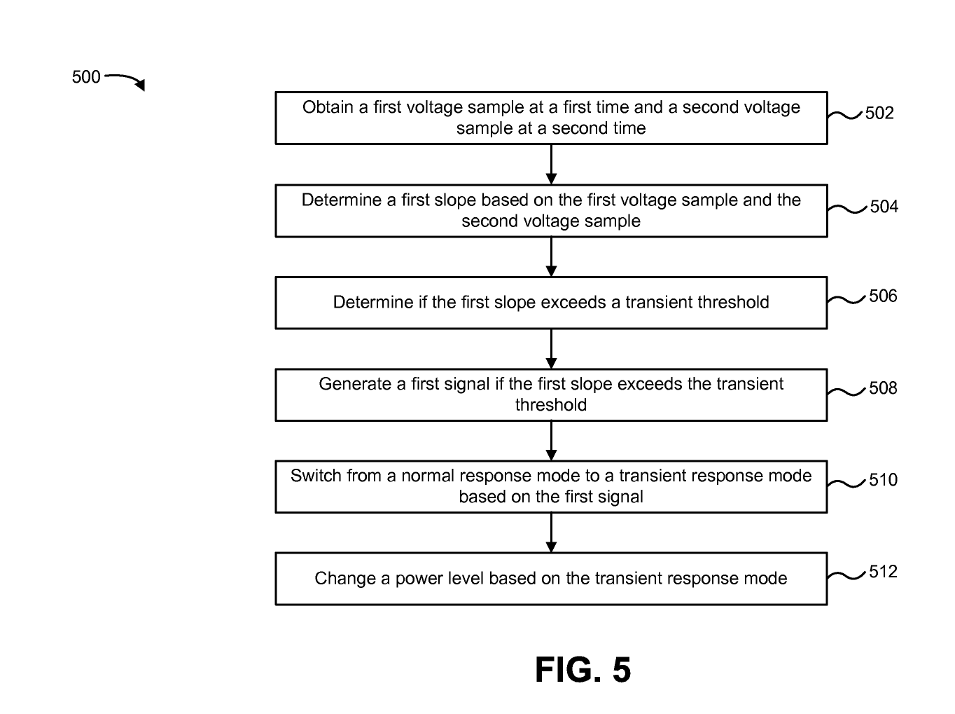

FIG. 5 is a flow diagram illustrating another configuration of a method 500 for detecting a transient on the circuitry 402. The circuitry 402 may obtain 502 a first voltage sample at a first time and a second voltage sample at a second time (e.g., voltage samples 408). Obtaining 502 a voltage sample may be similar to obtaining 202 a voltage sample described previously with respect to FIG. 2. The circuitry 402 may also determine 504 a first slope (e.g., slope determination 412) based on the first voltage sample and the second voltage sample. Determining 504 a slope may be similar to determining 204 a slope described previously with respect to FIG. 2.

The circuitry 402 may determine 506 if the first slope (e.g., slope determination 412) exceeds a transient threshold 418. For example, the circuitry 402 may compare the first slope with the transient threshold 418 to determine which is greater. In some cases, being greater than a threshold comprises being more negative than a threshold (e.g., for negative slope thresholds). In one configuration, this comparison may be performed by comparator circuitry (e.g., a comparator). In another configuration, this comparison may be performed by processing logic (running software and/or firmware, for example). The circuitry 402 may generate 508 a first signal (e.g., signal 416) if the first slope exceeds the transient threshold 418. Generating 508 a first signal may be similar to generating 206 a first signal described previously with respect to FIG. 2.

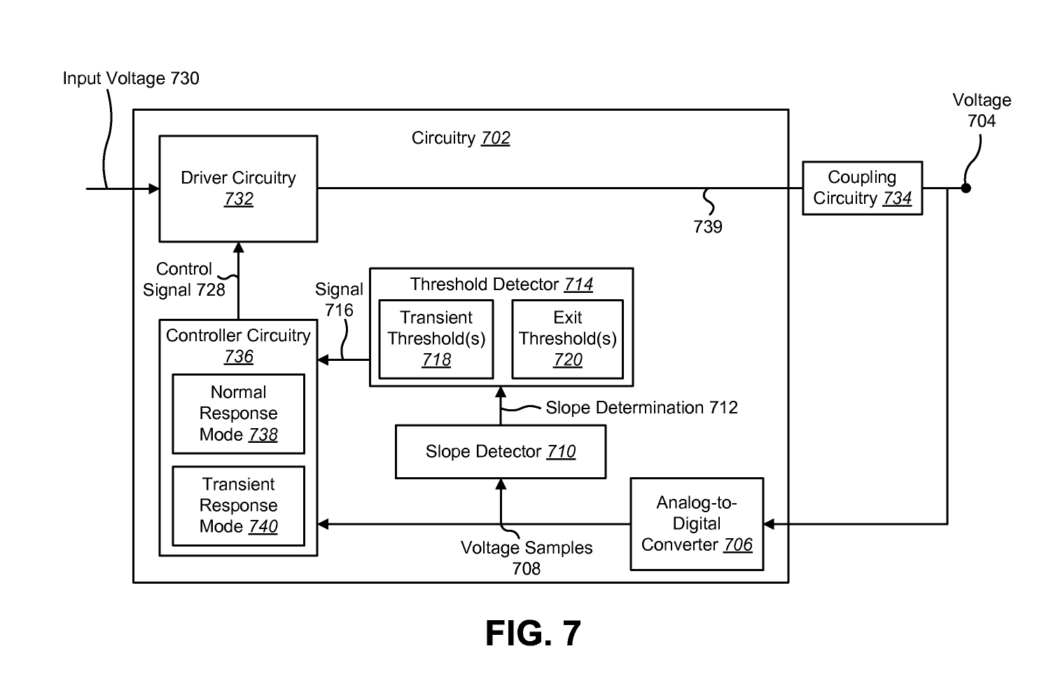

The circuitry 402 may switch 510 from a normal response mode to a transient response mode based on the first signal (e.g., signal 416). In one example, switching 510 from a normal response mode to a transient response mode comprises overriding a normal response control signal (e.g., normal control signal 424) with a transient response control signal (e.g., control signal 428). In another example, switching 510 comprises changing from a normal response mode to a transient response mode (described in greater detail below with respect to FIG. 7). In one configuration, the normal response mode may provide gradual (over several duty cycle periods, for example), incremental adjustments (e.g., increasing or decreasing the duty cycle by a small percentile). In contrast, the transient response mode may provide an immediate (when the first signal is received, for example), extensive adjustment (e.g., increasing the duty cycle to a maximum duty cycle or decreasing the duty cycle to a minimum duty cycle). If a transient is detected during a switching frame, then during the frame in which a transient is detected, the maximum duty cycle may be limited by any off-state time occurring during the frame previous to the detection of the transient. Similarly, the minimum duty cycle may be limited by any on-state time occurring during the frame previous to the detection of the transient. On subsequent frames, the maximum duty cycle may correspond to 100% duty cycle and a minimum duty cycle may correspond to 0% duty cycle.

The circuitry 402 may change 512 a power level based on the transient response mode. For example, the circuitry 402 may increase or decrease the duty cycle that is providing the voltage 404. For instance (e.g., the case of a voltage drop), the circuitry 402 may increase the power level (increasing the duty cycle to a maximum duty cycle, for example) based on the transient response mode (a transient response control signal, for example). Increasing the power level (from a normal duty cycle to a maximum duty cycle, for example) during a voltage drop may stop any further voltage loss and may correct any voltage drop that has occurred. In another instance (e.g., the case of a voltage spike), the circuitry 402 may decrease the power level (decreasing the duty cycle to a minimum duty cycle, for example) based on the transient response mode. Decreasing the power level (from a normal duty cycle to a minimum duty cycle, for example) during a voltage spike may stop any further voltage gain and may correct any voltage spike that has occurred. Thus, changing 512 a power level based on the transient response mode may allow for faster transient correction.

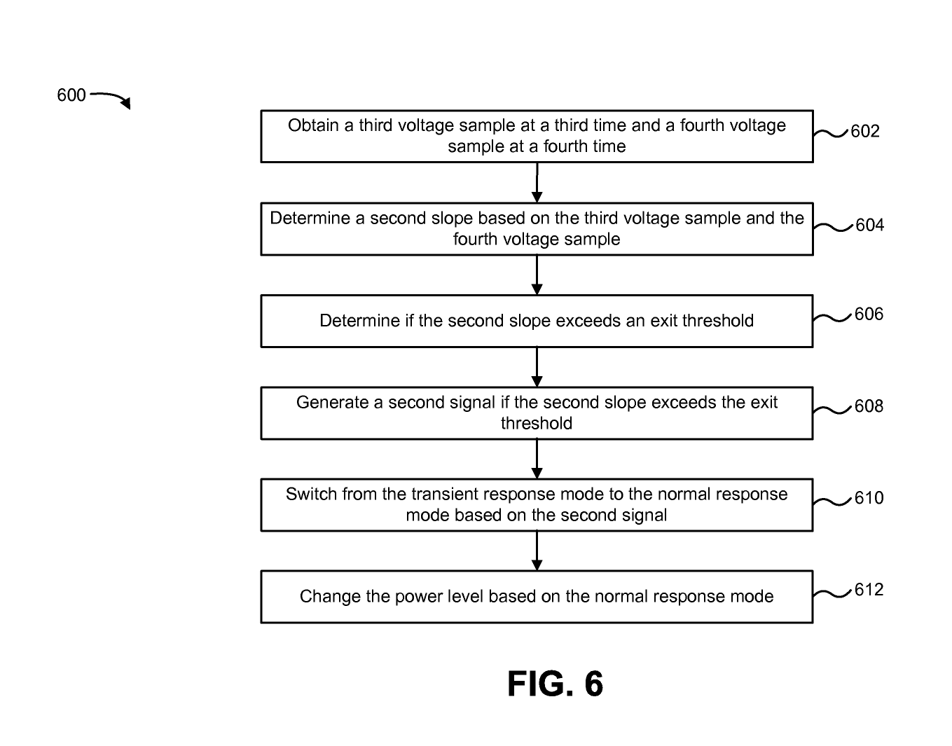

FIG. 6 is a flow diagram illustrating another configuration of a method 600 for detecting an exit condition on the circuitry 402. The circuitry 402 may obtain 602 a third voltage sample at a third time and a fourth voltage sample at a fourth time (e.g., voltage samples 408). Obtaining 602 these voltage samples may be similar to obtaining 302 the voltage samples described previously with respect to FIG. 3. The circuitry 402 may also determine 604 a second slope (e.g., slope determination 412) based on the third voltage sample and the fourth voltage sample. Determining 604 a slope may be similar to determining 304 a slope described previously with respect to FIG. 3.

The circuitry 402 may determine 606 if the second slope (e.g., slope determination 412) exceeds an exit threshold 420. For example, the circuitry 402 may compare the second slope with the exit threshold 420 to determine whether the second slope exceeds the exit threshold 420. In some configurations, multiple exit thresholds may be used. For example, the second slope may exceed a positive exit threshold (by being greater than the positive threshold, for example) or may exceed a negative exit threshold (by being less than the negative exit threshold, for example). In one configuration, this comparison may be performed by comparator circuitry (e.g., a comparator). In another configuration, this comparison may be performed by processing logic (running software and/or firmware, for example). The circuitry 402 may generate 608 a second signal (e.g., signal 416) if the second slope exceeds the exit threshold 420. Generating 608 a signal may be similar to generating 306 a signal described previously with respect to FIG. 3.

The circuitry 402 may switch 610 from a transient response mode to a normal response mode based on the second signal (e.g., signal 416). In one example, switching 610 from a transient response mode to a normal response mode comprises propagating a normal response control signal (e.g., normal control signal 424) as the control signal 428. In another example, switching 610 comprises changing from a transient response mode to a normal response mode (described in greater detail below with respect to FIG. 7).

The circuitry 402 may change 612 a power level based on the normal response mode. For example, the circuitry 402 may increase or decrease the duty cycle that is providing the voltage 404. For instance (e.g., in the case of a voltage drop), the circuitry 402 may decrease the power level (decreasing the duty cycle to a normal duty cycle, for example) based on the normal response mode. In another instance (e.g., in the case of a voltage spike), the circuitry 402 may increase the power level (increasing the duty cycle to a normal duty cycle, for example) based on the normal response mode.

The circuitry 402 may change 612 a power level based on the normal response mode. For example, the circuitry 402 may increase or decrease the duty cycle that is providing the voltage 404. For instance (e.g., in the case of a voltage drop), the circuitry 402 may decrease the power level (decreasing the duty cycle from a maximum duty cycle to a normal duty cycle, for example) based on the normal response mode (a normal control signal 424, for example). This decrease in the power level (from a maximum duty cycle to a normal duty cycle, for example) may allow for normal response mode operation following a transient response recovery (e.g., the transient has been stopped and corrected). In another instance (e.g., in the case of a voltage spike), the circuitry 402 may increase the power level (increasing the duty cycle from a minimum duty cycle to a normal duty cycle, for example) based on the normal response mode (a normal control signal 424, for example). This increase in power level (from a minimum duty cycle to a normal duty cycle, for example) may allow for normal response mode operation following the transient response recovery. Thus, changing 612 a power level based on the normal response mode may allow for normal response following a transient response mode correction.

FIG. 7 is a block diagram illustrating one example of circuitry 702, including controller circuitry 736 with a normal response mode 738 and a transient response mode 740, in which systems and methods for detecting a transient may be implemented. The circuitry 702 may be similar to the circuitry 402 described previously with respect to FIG. 4. Therefore, the descriptions associated with FIG. 4 may be equally applied to FIG. 7.

More specifically, the circuitry 702 may include driver circuitry 732 that may receive an input voltage 730 and may output a voltage 704 via coupling circuitry 734 (by providing a switch signal 739 to the coupling circuitry 734, for example). The driver circuitry 732 may be similar to the driver circuitry 432 described previously with respect to FIG. 4. The coupling circuitry 734 may be similar to the coupling circuitry 434 described previously with respect to FIG. 4. The circuitry 702 may also include an analog-to-digital converter 706 that may receive the voltage 704 and may output voltage samples 708. The analog-to-digital converter 706 may be similar to the analog-to-digital converter 406 described previously with respect to FIG. 4. The circuitry 702 may additionally include a slope detector 710 that may receive the voltage samples 708 and may output a slope determination 712. The slope detector 710 may be similar to the slope detector 410 described previously with respect to FIG. 4. The circuitry 702 may further include a threshold detector 714 that may receive the slope determination 712 and that may generate a signal 716 if the slope determination 712 exceeds a threshold (e.g., one of transient threshold(s) 718 or one of exit threshold(s) 720). The transient threshold(s) 718 and the exit threshold(s) 720 may be similar to the respective transient threshold(s) 418 and the exit threshold(s) 420 described previously with respect to FIG. 4. The threshold detector 714 may be similar to the threshold detector 414 described previously with respect to FIG. 4. However, instead of a controller 422 and controller override circuitry 426 as illustrated in FIG. 4, the circuitry 702 includes the controller circuitry 736.

The controller circuitry 736 may be coupled to the threshold detector 714 and to the analog-to-digital converter 706 and may receive a signal 716 from the threshold detector 714 and may receive voltage samples 708 from the analog-to-digital converter 706. The controller circuitry 736 may control driver circuitry 732 with a control signal 728 based on a normal response mode 738 or a transient response mode 740. For example, the controller circuitry 736 may control the driver circuitry 732 in the normal response mode 738 until the controller circuitry 736 receives a first signal (e.g., signal 716) that indicates a transient. When the first signal is received, the controller circuitry 736 may switch from controlling the driver circuitry 732 in a normal response mode 738 to controlling the driver circuitry 732 in a transient response mode 740. The controller circuitry 736 may control the driver circuitry 732 in the transient response mode 740 until a second signal (e.g., 716) that indicates an exit condition is received. When the second signal is received, the controller circuitry 736 may switch back to controlling the driver circuitry 732 in the normal response mode 738. As described previously with respect to switching 510, 610, the normal response mode 738 may be configured for correcting small (e.g., with a slope that does not exceed a transient threshold) voltage variations and the transient response mode 740 may be configured for correcting large (e.g., with a slope that exceeds a transient threshold) voltage variations.

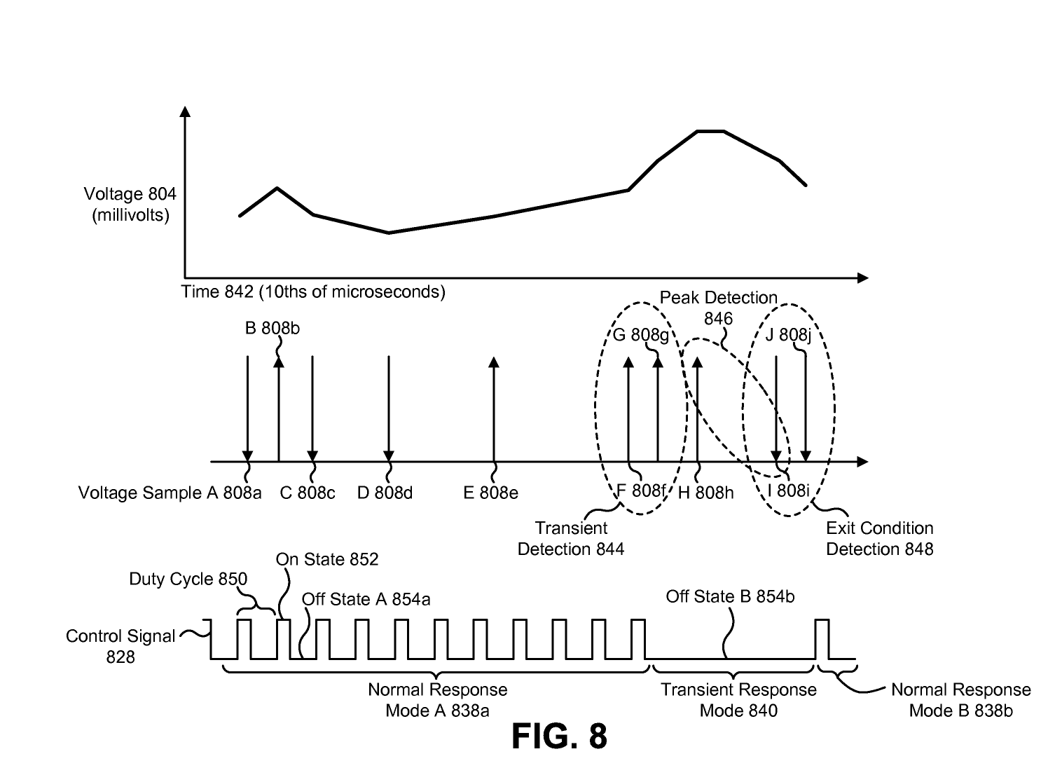

FIG. 8 is a diagram illustrating one example of a voltage variation and how a transient (e.g., transient detection 844) and an exit condition (e.g., exit condition detection 848) may be detected. FIG. 8 may illustrate the operation of any of the circuitries 102, 402, 702 described previously. For example, the voltage 804 may correspond to one or more of the voltages 104, 404, 704 described previously. Positive variations in the voltage 804 may be compared with a positive threshold (e.g., transient threshold, exit threshold) and negative variations in the voltage 804 may be compared with a negative threshold (e.g., transient threshold, exit threshold). A slope that exceeds a positive threshold may be more positive than the positive threshold. A slope that exceeds a negative threshold may be more negative than the negative threshold.

In one example, a voltage 804 may vary over time 842 as illustrated. Variations in the voltage 804 may be caused by a variety of factors. Examples of voltage variation include noise, fast load transients, slow load transients, etc. Voltage samples A-J 808a-j of the voltage 804 may be taken at various intervals of time (e.g., time 842). The voltage samples A-J 808a-j illustrated may only be a selection of the voltage samples that are taken over time (e.g., time 842). Voltage samples A-C 808a-c may correspond to a voltage variation due to noise. In one configuration, the threshold (e.g., transient threshold 418 and/or exit threshold 420 as illustrated in FIG. 4) may be configured so that voltage variations due to noise may not exceed the threshold. In other words, the threshold rate of change (e.g., slope) may be selected to filter out voltage variations corresponding to noise. Voltage samples C-D 808c-d may correspond to a voltage variation drop over an extended a period of time 842. In this case, the slope corresponding to voltage samples C-D 808c-d does not exceed (e.g., is less negative than) the negative transient threshold. Voltage samples E-F 808e-f may correspond to a slow voltage variation gain over an extended period of time 842. In this case, the slope corresponding to voltage samples D-E 808d-e does not exceed (e.g., is less than) a positive transient threshold.

Voltage samples F-G 808f-g may correspond to a voltage variation due to a fast load transient (e.g., a fast unload transient). As illustrated, voltage samples F-G 808f-g may correspond to a sufficient change in the voltage 804 over time 842 to exceed a positive transient threshold and constitute a transient detection 844 (where transient detection 844 time may be approximately 100 ns). For example, the slope (e.g., a first slope) corresponding with voltage samples F-G 808f-g may exceed a positive threshold (e.g., transient threshold 418). In one configuration, once a transient is detected (e.g., transient detection 844), a peak detection 846 may be sought before an exit condition is sought. As illustrated, voltage samples H-I 808h-i may correspond to a peak (e.g., peak detection 846) because the increasing slope switches to a decreasing slope (e.g., change in concavity). Following the transient detection 844, an exit condition may be sought. An exit condition may require a slope that exceeds a threshold (e.g., exit threshold 420). As illustrated, voltage samples I-J 808i-j may correspond to a sufficient change in the voltage 804 over time 842 to exceed a negative exit threshold and constitute an exit condition detection 848.

As illustrated, a control signal 828 may specify a pulse train (for driving driver circuitry 432 as illustrated in FIG. 4, for example). The pulse train may include one or more duty cycles 850. A duty cycle 850 may include an on state 852 and/or off state A 854a. For example, a 30% duty cycle 850 may correspond to an on state 852 for 30% of the time (e.g., time 842) and off state 854a A for 70% of the time. In the example illustrated, the control signal 828 may specify a 30% duty cycle 850 during normal response mode A 838a. In response to a transient detection (e.g., transient detection 844) the control signal 828 may specify a 0% duty cycle 850 (e.g., off state B 854b for one or more partial and/or full duty cycles 850) according to a transient response mode 840 (e.g., to respond to the spike in the voltage 804). As illustrated, upon the detection of a transient (e.g., transient detection 844) normal response mode A 838a may be switched to a transient response mode 840. The switch the from normal response mode A 838a to the transient response mode 840 may correspond to a change in power (e.g., a change from 30% duty cycle 850 to 0% duty cycle 850). The transient response mode 840 may continue until the detection of an exit condition (e.g., exit condition detection 848). Upon the detection of the exit condition, the transient response mode 840 may be switched to normal response mode B 838b. The switch from the transient response mode 840 to normal response mode B 838b may also correspond to a change in power (e.g., a change from 0% duty cycle 850 to 30% duty cycle 850). In this scenario (e.g., a voltage spike), the transient response mode 840 reduced the duty cycle 850 to a minimum duty cycle 850 (e.g., 0%). In a different scenario (e.g., a voltage drop), a transient response mode may increase the duty cycle to a maximum duty cycle 850 (e.g., 100%) to properly respond to the transient.

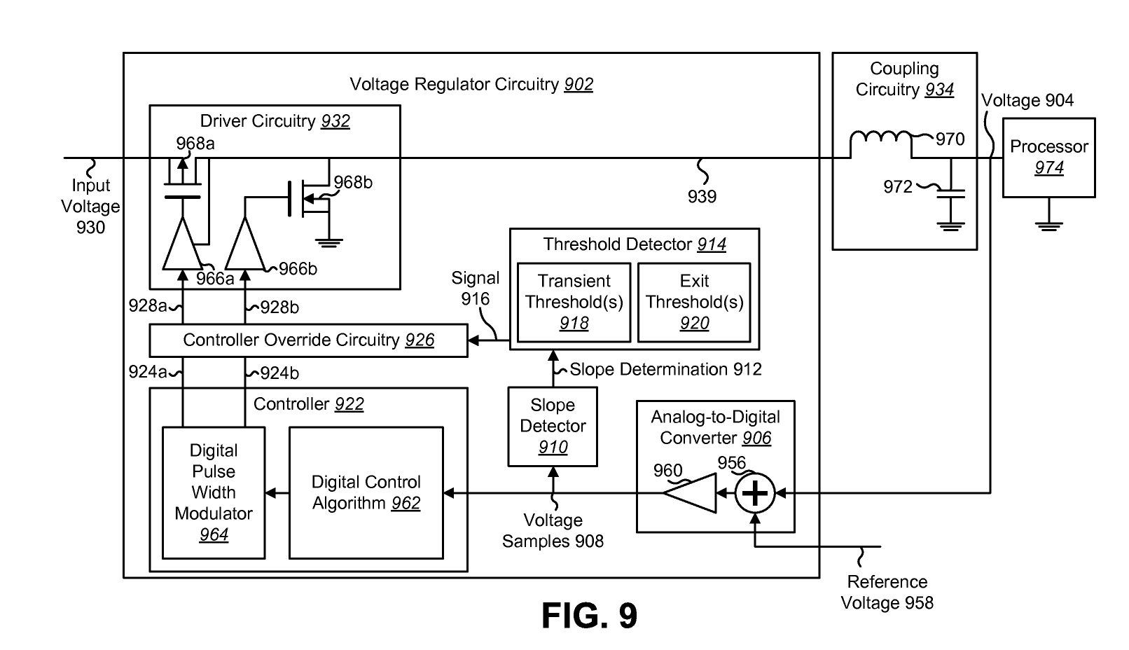

FIG. 9 is a block diagram illustrating one example of voltage regulator circuitry 902 for supplying a voltage 904 to a processor 974. The voltage regulator circuitry 902 may illustrate one example of a configuration in which systems and methods for detecting a transient may be implemented.

The voltage regulator circuitry 902 may be coupled to coupling circuitry 934 and may provide a voltage 904 to the processor 974 through the coupling circuitry 934. In one configuration, the voltage regulator circuitry 902 and the coupling circuitry 934 may comprise a buck converter topology. In this configuration, the coupling circuitry 934 may include an inductor 970 and a capacitor 972. In some configurations, the coupling circuitry 934 may comprise additional and/or alternative components that may implement additional and/or alternative converter topologies when combined with the regulator circuitry 902. In one configuration, the voltage regulator circuitry 902 may comprise a switching regulator.

The voltage regulator circuitry 902 may supply a voltage 904 to the processor 974. The processor 974 (e.g., general purpose single- or multi-chip microprocessor, special purpose microprocessor, microcontroller, programmable gate array, etc.) may have unique power usage requirements. For example, the processor 974 may require milliamps of current during an idle state and then may quickly require amperes of current when an active process begins. This nearly instantaneous change in current (e.g., fast load transient) may result in a dramatic voltage variation. However, the processor 974 may require a voltage 904 that is within a strict tolerance (e.g., plus or minus 40 mV). Thus, a special response may be required to respond to dramatic voltage variations (e.g., variations of the voltage 904). In one configuration, the systems and methods described herein may be used to detect a transient (e.g., voltage variation) so that a special response (e.g., a transient response) may be triggered.

As illustrated in FIG. 9, an analog-to-digital converter 906 may be coupled to a line that supplies the voltage 904 to the processor 974. The analog-to-digital converter 906 may include a summer 956 to determine the error (e.g., error voltage) between the voltage 904 and a reference voltage 958 (e.g., a desired or target voltage). The analog-to-digital converter 906 may also include a comparator 960 for discretizing the error into voltage samples 908. In another configuration, the analog-to-digital converter 906 may be a window flash ADC. One example of a window flash ADC may include eight comparators at reference voltages 11 mV apart (at ±5.5 mV, ±16.5 mV, ±27.5 mV, and ±38.5 mV, for example). The analog-to-digital converter 906 may be clock such that conversion occurs at an approximately constant rate (e.g., 10 megahertz (MHz)). The analog-to-digital converter 906 may be coupled to a slope detector 910 and to the controller 922.

The controller 922 may receive the voltage samples 908 and may determine a pulse width modulation scheme based on a digital control algorithm 962. The controller 922 may include the digital control algorithm 962 and a digital pulse width modulator 964. The digital pulse width modulator 964 may output a normal control signal 924 (e.g., a pulse train) based on the output of the digital control algorithm. The normal control signal 924 may include two differential normal control signals 924a-b, where a first normal control signal 924a is an approximate complement or inverse of a second normal control signal 924b. For example, the digital pulse width modulator 964 may output separate commands (e.g., normal control signal 924a, 924b) for the respective pull-up portion and pull-down portion of driver circuitry 932.

The slope detector 910 may determine a slope (e.g., slope determination 912) based on the voltage samples 908. The slope detector 910 may be similar to the slope detector 410 described previously with respect to FIG. 4. A threshold detector 914 may receive the slope determination 912 and may generate a signal 916 if the slope determination 912 exceeds a threshold (e.g., one or more transient thresholds 918 or one or more exit thresholds 920). The transient threshold 918 and the exit threshold 920 may be similar to the respective transient threshold(s) 418 and the exit threshold(s) 420 described previously with respect to FIG. 4. The threshold detector 914 may be similar to the threshold detector 414 described previously with respect to FIG. 4. In one configuration, a first signal (e.g., signal 916) may be generated when a slope determination 912 exceeds a transient threshold 918 and a second signal (e.g., signal 916) may be generated when a slope determination 912 exceeds an exit threshold 920.

Controller override circuitry 926 may be coupled to the threshold detector 914 and to the controller 922. The controller override circuitry 926 may receive the normal control signals 924a-b from the controller 922 and the signal 916 from the threshold detector 914. The controller override circuitry 926 may output a first control signal 928a for the pull-up circuitry of the driver circuitry 932 and a second control signal 928b for the pull-down circuitry of the driver circuitry 932. The first control signal 928a and the second control signal 928b may be differential signals (e.g., approximate complements or the inverse of each other). During normal operation (e.g., normal response mode, when a transient has not been detected), the controller override circuitry 926 may propagate the normal control signals 924a-b as the control signals 928a-b (e.g., the control signals 928a-b are the same as the normal control signals 924a-b). During a transient condition (e.g., transient response mode, between the transient detection the exit condition detection, for example), the controller override circuitry 926 may override the normal control signals 924a-b with a transient response signal. For example, the transient response signal may be a control signal for an increased or maximum duty cycle or a decreased or minimum duty cycle based on the signal 916. In another example, the transient response signal may be a control signal for 90% or 10% duty cycle based on the signal 916. The controller override circuitry 926 may override the normal control signals 924a-b with the transient response signals. The controller override circuitry 926 may send the transient response signals to the driver circuitry 932 as control signals 928a-b.

The driver circuitry 932 may receive an input voltage 930 and control signals 928a-b. The pulse width modulation pulse train for the pull-up circuitry may be received by buffer A 966a and the pulse width modulation train for the pull-down circuitry may be received by buffer B 966b. In some configurations, each buffer 966a-b may include four tapered inverters ranging from small to large, where each subsequent inverter is approximately three times larger than the previous inverter to constitute buffers 966a-b that can drive large output field effect transistors (FETs) 968a-b. The buffers 966a-b may drive the gates of the respective pull-up and pull-down circuitry. As illustrated, buffer A 966a may drive the gate of a p-type metal oxide semiconductor field effect transistor (MOSFET) 968a and buffer B 966b may drive the gate of the n-type MOSFET 968b. The p-type MOSFET 968a may pull-up the switch signal 939 to the input voltage 930 during each pulse of the pulse width modulation train on the first control signal 928a. Similarly, the n-type MOSFET 968b may pull-down the switch signal 939 to ground during each pulse of the pulse width modulation train on the second control signal 928b. The combination of the voltage pull-up and/or the voltage pull-down may create a duty cycle (based on the pulse width modulation scheme of either the controller 922 (e.g., normal response mode) or the controller override circuitry 926 (e.g., transient response mode), for example). The driver circuitry 932 may output the duty cycle for supplying the voltage 904 to the processor 974.

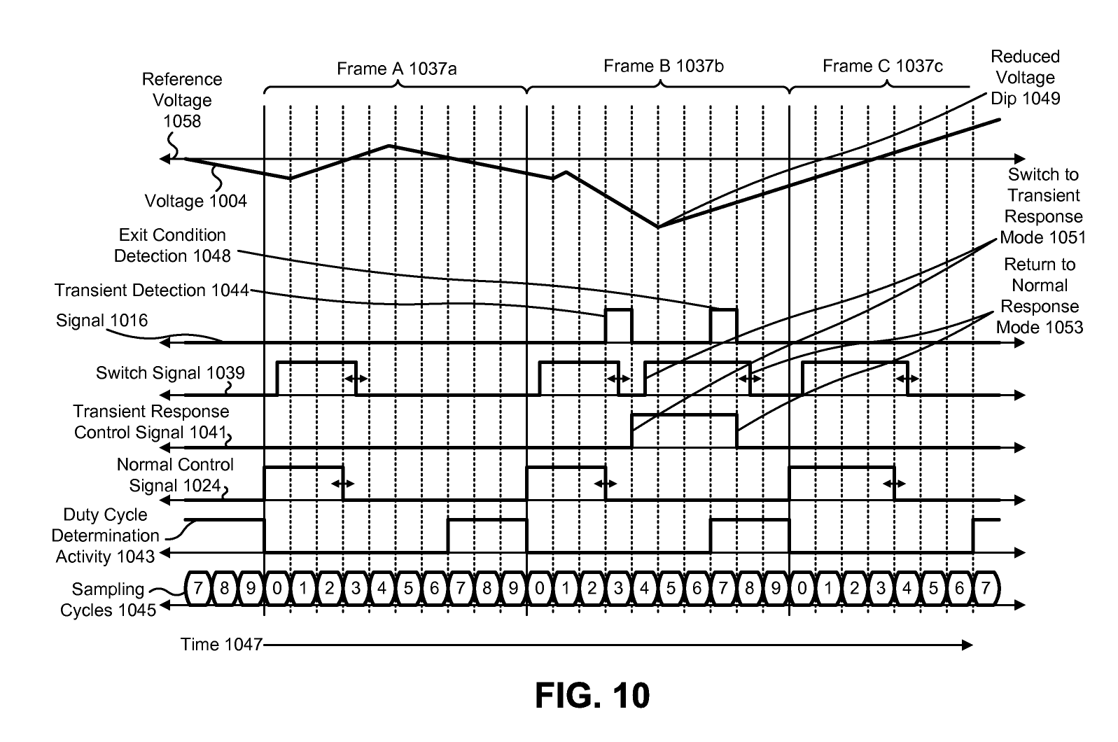

FIG. 10 is a timing diagram illustrating one example of transient detection in accordance with the systems and method disclosed herein. In particular, FIG. 10 illustrates one example of the signal and/or operation timing on circuitry 402 over time 1047. In this example, circuitry 402 operations may occur in accordance with sampling cycles 1045. For example, each sampling cycle 1045 may be an amount of time for the analog-to-digital converter 406 to produce another voltage sample 408. However, in other configurations, circuitry 402 operations may occur in accordance with clock cycles, amounts of time or other time quanta.

In this example, the circuitry 402 (e.g., controller 422) may determine a duty cycle for a following frame when duty cycle determination activity 1043 is high. For instance, the duty cycle for frame A 1037a may be determined prior to frame A 1037a. This duty cycle for frame A 1037a may be reflected or indicated by a normal control signal 1024 and/or a switch signal 1039. For example, the normal control signal 1024 may go high for a proportion of frame A 1037a (during “on time,” for instance) and may go low for a proportion of frame A 1037a (during “off time,” for instance). In frame A 1037a, the normal control signal 1024 is high for three sampling cycles 1045 and low for seven sampling cycles 1045. In some configurations, a switch signal 1039 may be an input voltage (e.g., input voltage 430) as it is switched on and off over time 1047. The switch signal 1039 may correspond to the normal control signal 1024 while in a normal response mode. As illustrated in FIG. 10, a switch signal 1039 may be delayed compared to the normal control signal 1024 (on account of propagation delay and/or driver switching delay, for example).

In this example, a voltage 1004 is illustrated (in relation to a reference voltage 1058). As shown in FIG. 10, the voltage 1004 may vary over time 1047 and may decrease to a reduced voltage dip 1049. In frame A 1037a, no transients occur and the circuitry 402 may operate normally. In frame B 1037b, a transient may occur. In this case, the transient is a drop in voltage 1004. In frame B 1037b, transient detection 1044 occurs as indicated by the signal 1016. For instance, the threshold detector 414 may produce the signal 1016 that indicates transient detection 1044.

When the transient detection 1044 occurs in frame B 1037b, a transient response control signal 1041 may go high approximately upon switching 1051 to the transient response mode. As illustrated in FIG. 10, the switch signal 1039 may then respond to the transient response control signal 1041 and not to the normal control signal 1024 when the normal control signal is overridden. For example, the controller override circuitry 426 may override the normal control signal 1024 with the transient response control signal 1041 while in transient response mode.

As illustrated in FIG. 10, the voltage 1004 may begin to increase in response to the increased duty cycle reflected by the switch signal 1039. In frame B 1037b, an exit condition detection 1048 may occur as indicated by the signal 1016. For example, the threshold detector 414 may detect the occurrence of an exit condition (as indicated by the positive slope in voltage 1004 after the bottom of the reduced voltage dip 1049) and indicate the exit condition detection 1048 with the signal 1016. The transient response control signal 1041 may then go low upon returning 1053 to normal response mode. For example, the controller override circuitry 426 may discontinue overriding the normal control signal 424. Thus, the switch signal 1039 may correspond to the normal control signal 1024 in frame C 1037c.

As a result of switching 1051 to transient response mode, the voltage 1004 may recover from the transient at the reduced voltage dip 1049. By detecting a transient based on slope, for example, the circuitry 402 may respond more quickly to transients, which may result in a reduced voltage dip 1049 or a reduced voltage spike. It should be noted that if the transient were a voltage spike instead of a reduced voltage dip 1049, the transient response control signal may have reduced the amount of time the switch signal 1039 would be high (e.g., “on time”), thereby reducing the voltage spike.

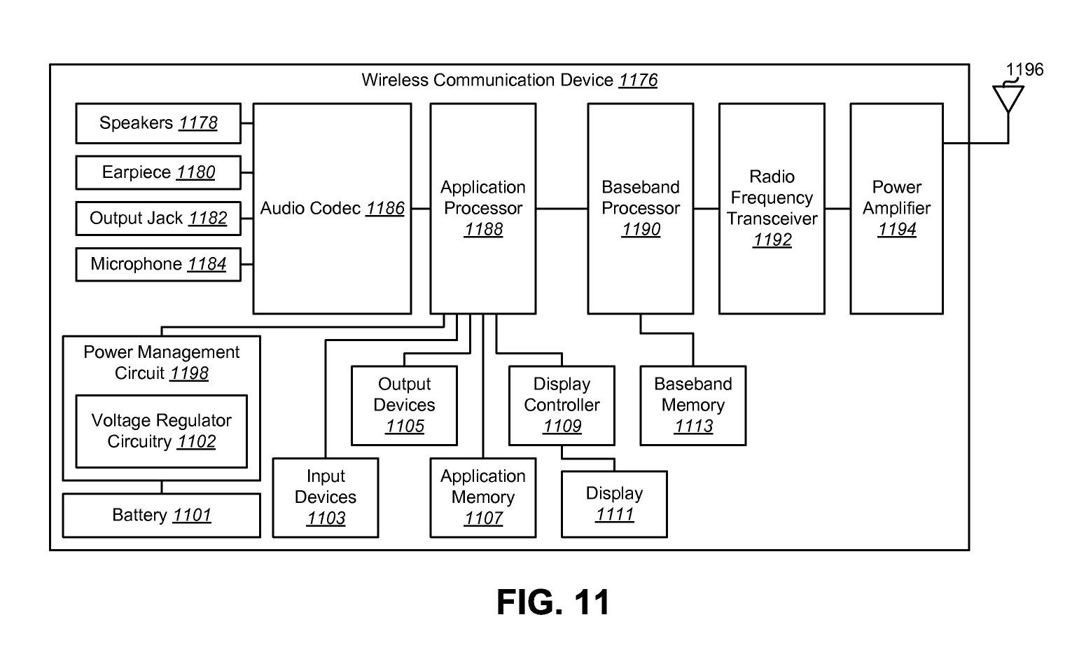

FIG. 11 is a block diagram illustrating one configuration of a wireless communication device 1176 in which systems and methods for detecting a transient may be implemented. The wireless communication device 1176 may include an application processor 1188. The application processor 1188 generally processes instructions (e.g., runs programs) to perform functions on the wireless communication device 1176. The application processor 1188 may be coupled to an audio coder/decoder (codec) 1186.

The audio codec 1186 may be an electronic device (e.g., integrated circuit) used for coding and/or decoding audio signals. The audio codec 1186 may be coupled to one or more speakers 1178, an earpiece 1180, an output jack 1182 and/or one or more microphones 1184. The speakers 1178 may include one or more electro-acoustic transducers that convert electrical or electronic signals into acoustic signals. For example, the speakers 1178 may be used to play music or output a speakerphone conversation, etc. The earpiece 1180 may be another speaker or electro-acoustic transducer that can be used to output acoustic signals (e.g., speech signals) to a user. For example, the earpiece 1180 may be used such that only a user may reliably hear the acoustic signal. The output jack 1182 may be used for coupling other devices to the wireless communication device 1176 for outputting audio, such as headphones. The speakers 1178, earpiece 1180 and/or output jack 1182 may generally be used for outputting an audio signal from the audio codec 1186. The one or more microphones 1184 may be one or more acousto-electric transducers that convert an acoustic signal (such as a user's voice) into electrical or electronic signals that are provided to the audio codec 1186.

The application processor 1188 may also be coupled to a power management circuit 1198. It should be noted that the power management circuit 1198 may be additionally or alternatively coupled to one or more of the elements illustrated as included within the wireless communication device 1176. One example of the power management circuit 1198 is a power management integrated circuit (PMIC), which may be used to manage the electrical power consumption of the wireless communication device 1176. The power management circuit 1198 may be coupled to a battery 1101. The battery 1101 may generally provide electrical power to the wireless communication device 1176.

The power management circuit 1198 may include voltage regulator circuitry 1102. The voltage regulator circuitry 1102 may be one example of one or more of the circuitries 102, 402, 702, 902 described above.

The application processor 1188 may be coupled to one or more input devices 1103 for receiving input. Examples of input devices 1103 include infrared sensors, image sensors, accelerometers, touch sensors, keypads, wired ports, wireless ports, etc. The input devices 1103 may allow user interaction with the wireless communication device 1176. Additionally or alternatively, the input devices 1103 may enable the wireless communication device 1176 to communicate with one or more other electronic devices. The application processor 1188 may also be coupled to one or more output devices 1105. Examples of output devices 1105 include printers, projectors, screens, haptic devices, wired ports, wireless ports, etc. The output devices 1105 may allow the wireless communication device 1176 to produce output that may be experienced by a user. Additionally or alternatively, the output devices 1105 may enable the wireless communication device 1176 to communicate with one or more other electronic devices.

The application processor 1188 may be coupled to application memory 1107. The application memory 1107 may be any electronic device that is capable of storing electronic information. Examples of application memory 1107 include double data rate synchronous dynamic random access memory (DDRAM), synchronous dynamic random access memory (SDRAM), flash memory, etc. The application memory 1107 may provide storage for the application processor 1188. For instance, the application memory 1107 may store data and/or instructions for the functioning of programs that are run on the application processor 1188.

The application processor 1188 may be coupled to a display controller 1109, which in turn may be coupled to a display 1111. The display controller 1109 may be a hardware block that is used to generate images on the display 1111. For example, the display controller 1109 may translate instructions and/or data from the application processor 1188 into images that can be presented on the display 1111. Examples of the display 1111 include liquid crystal display (LCD) panels, light emitting diode (LED) panels, cathode ray tube (CRT) displays, plasma displays, etc.

The application processor 1188 may be coupled to a baseband processor 1190. The baseband processor 1190 generally processes communication signals. For example, the baseband processor 1190 may demodulate and/or decode (e.g., channel decode) received signals. Additionally or alternatively, the baseband processor 1190 may encode (e.g., channel encode) and/or modulate signals in preparation for transmission.

The baseband processor 1190 may be coupled to a baseband memory 1113. The baseband memory 1113 may be any electronic device capable of storing electronic information, such as SDRAM, DDRAM, flash memory, etc. The baseband processor 1190 may read information (e.g., instructions and/or data) from and/or write information to the baseband memory 1113. Additionally or alternatively, the baseband processor 1190 may use instructions and/or data stored in the baseband memory 1113 to perform communication operations.

The baseband processor 1190 may be coupled to a radio frequency (RF) transceiver 1192. The RF transceiver 1192 may be coupled to a power amplifier 1194 and one or more antennas 1196. The RF transceiver 1192 may transmit and/or receive radio frequency signals. For example, the RF transceiver 1192 may transmit an RF signal using a power amplifier 1194 and one or more antennas 1196. The RF transceiver 1192 may also receive RF signals using the one or more antennas 1196.

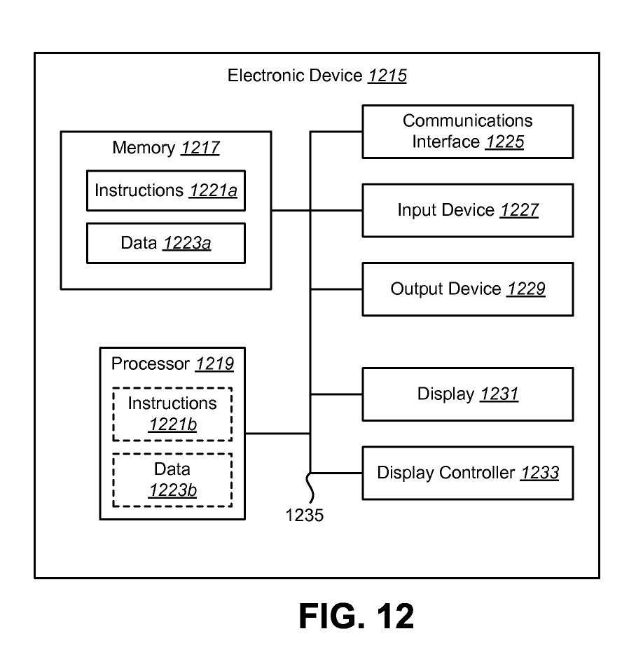

FIG. 12 illustrates various components that may be utilized in an electronic device 1215. The illustrated components may be located within the same physical structure or in separate housings or structures. Examples of electronic devices 1215 may include cellular phones, smartphones, computers, televisions, etc. The electronic device 1215 may be configured similarly to one or more of the circuitries 102, 402, 702, 902 described previously. The electronic device 1215 includes a processor 1219. The processor 1219 may be a general purpose single- or multi-chip microprocessor (e.g., an ARM), a special purpose microprocessor (e.g., a digital signal processor (DSP)), a microcontroller, a programmable gate array, etc. The processor 1219 may be referred to as a central processing unit (CPU). Although just a single processor 1219 is shown in the electronic device 1215 of FIG. 12, in an alternative configuration, a combination of processors (e.g., an ARM and DSP) could be used.

The electronic device 1215 also includes memory 1217 in electronic communication with the processor 1219. That is, the processor 1219 can read information from and/or write information to the memory 1217. The memory 1217 may be any electronic component capable of storing electronic information. The memory 1217 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof.

Data 1223a and instructions 1221a may be stored in the memory 1217. The instructions 1221a may include one or more programs, routines, sub-routines, functions, procedures, etc. The instructions 1221a may include a single computer-readable statement or many computer-readable statements. The instructions 1221a may be executable by the processor 1219 to implement one or more of the methods 200, 300, 500, 600 described above. Executing the instructions 1221a may involve the use of the data 1223a that is stored in the memory 1217. FIG. 12 shows some instructions 1221b and data 1223b being loaded into the processor 1219 (which may come from instructions 1221a and data 1223a).

The electronic device 1215 may also include one or more communication interfaces 1225 for communicating with other electronic devices. The communication interfaces 1225 may be based on wired communication technology, wireless communication technology, or both. Examples of different types of communication interfaces 1225 include a serial port, a parallel port, a Universal Serial Bus (USB), an Ethernet adapter, an IEEE 1394 bus interface, a small computer system interface (SCSI) bus interface, an infrared (IR) communication port, a Bluetooth wireless communication adapter, an IEEE 802.11 wireless communication adapter and so forth.

The electronic device 1215 may also include one or more input devices 1227 and one or more output devices 1229. Examples of different kinds of input devices 1227 include a keyboard, mouse, microphone, remote control device, button, joystick, trackball, touchpad, lightpen, etc. Examples of different kinds of output devices 1229 include a speaker, printer, etc. One specific type of output device which may be typically included in an electronic device 1215 is a display device 1231. Display devices 1231 used with configurations disclosed herein may utilize any suitable image projection technology, such as a cathode ray tube (CRT), liquid crystal display (LCD), light-emitting diode (LED), gas plasma, electroluminescence, or the like. A display controller 1233 may also be provided, for converting data stored in the memory 1217 into text, graphics, and/or moving images (as appropriate) shown on the display device 1231.

The various components of the electronic device 1215 may be coupled together by one or more buses, which may include a power bus, a control signal bus, a status signal bus, a data bus, etc. For simplicity, the various buses are illustrated in FIG. 12 as a bus system 1235. It should be noted that FIG. 12 illustrates only one possible configuration of an electronic device 1215. Various other architectures and components may be utilized.

In the above description, reference numbers have sometimes been used in connection with various terms. Where a term is used in connection with a reference number, this may be meant to refer to a specific element that is shown in one or more of the Figures. Where a term is used without a reference number, this may be meant to refer generally to the term without limitation to any particular Figure.

The term “exceed” and variations thereof may mean more positive than a positive value and/or more negative than a negative value. In other words, with respect to comparing a slope with a threshold, a slope of −2.1 exceeds a slope of −2.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. Disk and disc, as used herein, includes compact disc (CD), laser disc, optical disc, digital versatile disc (DVD), floppy disk and Blu-Ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. Circuitry configured for detecting a transient, comprising:
an analog-to-digital converter that obtains a first voltage sample at a first time and a second voltage sample at a second time;
a slope detector coupled to the analog-to-digital converter, wherein the slope detector determines a first slope based on the first voltage sample and the second voltage sample; and
a threshold detector coupled to the slope detector, wherein the threshold detector generates a first signal if the first slope exceeds a transient threshold.

2. The circuitry of claim 1, further comprising:
controller override circuitry coupled to the threshold detector, wherein the controller override circuitry switches from a normal response mode to a transient response mode based on the first signal; and
driver circuitry coupled to the controller override circuitry, wherein the driver circuitry changes a power level based on the transient response mode.

3. The circuitry of claim 2, wherein the analog-to-digital converter further obtains a third voltage sample at a third time and a fourth voltage sample at a fourth time, wherein the slope detector further determines a second slope based on the third voltage sample and the fourth voltage sample, and wherein the threshold detector further generates a second signal if the second slope exceeds an exit threshold.

4. The circuitry of claim 3, wherein the controller override circuitry further switches from the transient response mode to the normal response mode based on the second signal, and wherein the driver circuitry further changes the power level based on the normal response mode.

5. The circuitry of claim 1, wherein the first voltage sample and the second voltage sample comprise samples of a direct current voltage.

6. The circuitry of claim 5, wherein the direct current voltage is a supply voltage.

7. The circuitry of claim 1, wherein the circuitry is included in a buck converter.

8. A method for detecting a transient with circuitry, comprising:
obtaining a first voltage sample at a first time and a second voltage sample at a second time;
determining a first slope based on the first voltage sample and the second voltage sample; and
generating a first signal if the first slope exceeds a transient threshold.

9. The method of claim 8, further comprising:
switching from a normal response mode to a transient response mode based on the first signal; and
changing a power level based on the transient response mode.

10. The method of claim 9, further comprising:
obtaining a third voltage sample at a third time and a fourth voltage sample at a fourth time;
determining a second slope based on the third voltage sample and the fourth voltage sample; and
generating a second signal if the second slope exceeds an exit threshold.

11. The method of claim 10, further comprising:
switching from the transient response mode to the normal response mode based on the second signal; and
changing the power level based on the normal response mode.

12. The method of claim 8, wherein the first voltage sample and the second voltage sample comprise samples of a direct current voltage.

13. The method of claim 12, wherein the direct current voltage is a supply voltage.

14. The method of claim 8, wherein the method is performed by a buck converter.

15. A computer-program product for detecting a transient, comprising a non-transitory tangible computer-readable medium having instructions thereon, the instructions comprising:
code for causing circuitry to obtain a first voltage sample at a first time and a second voltage sample at a second time;
code for causing the circuitry to determine a first slope based on the first voltage sample and the second voltage sample; and
code for causing the circuitry to generate a first signal if the first slope exceeds a transient threshold.

16. The computer-program product of claim 15, further comprising:
code for causing the circuitry to switch from a normal response mode to a transient response mode based on the first signal; and
code for causing the circuitry to change a power level based on the transient response mode.

17. The computer-program product of claim 16, further comprising:
code for causing the circuitry to obtain a third voltage sample at a third time and a fourth voltage sample at a fourth time;
code for causing the circuitry to determine a second slope based on the third voltage sample and the fourth voltage sample; and
code for causing the circuitry to generate a second signal if the second slope exceeds an exit threshold.

18. The computer-program product of claim 17, further comprising:
code for causing the circuitry to switch from the transient response mode to the normal response mode based on the first signal; and
code for causing the circuitry to change the power level based on the normal response mode.

19. An apparatus for detecting a transient, comprising:
means for obtaining a first voltage sample at a first time and a second voltage sample at a second time;
means for determining a first slope based on the first voltage sample and the second voltage sample; and
means for generating a first signal if the first slope exceeds a transient threshold.

20. The apparatus of claim 19, further comprising:
means for switching from a normal response mode to a transient response mode based on the first signal; and
means for changing a power level based on the transient response mode.

21. The apparatus of claim 20, further comprising:
means for obtaining a third voltage sample at a third time and a fourth voltage sample at a fourth time;
means for determining a second slope based on the third voltage sample and the fourth voltage sample; and
means for generating a second signal if the second slope exceeds an exit threshold.

22. The apparatus of claim 21, further comprising:
means for switching from the transient response mode to the normal response mode based on the first signal; and
means for changing the power level based on the normal response mode.
